(19) United States
(12) Patent Application Publication
(10) Pub. No.: US 2024/0030101 A1
(43) Pub. Date: Jan. 25, 2024

(54) Power Module and Method for Producing a Power Module

(71) Applicant: Hitachi Energy Switzerland AG, Baden (CH)

(72) Inventors: Niko Pavlicek, Zürich (CH); Didier Cottet, Zürich (CH); Thomas Gradinger, Aarau Rohr (CH); Chunlei Liu, Oberrohrdorf (CH); Fabian Mohn, Ennetbaden (CH); Giovanni Salvatore, Gorizia (IT); Juergen Schuderer, Zürich (CH); Daniele Torresin, Baden (CH); Felix Traub, Basel (CH)

(21) Appl. No.: 18/026,924

(22) PCT Filed: Sep. 16, 2021
(86) PCT No.: PCT/EP2021/075486

§ 371 Date: Mar. 17, 2023

(30) Foreign Application Priority Data
Sep. 17, 2020 (EP) 20196695.9

(51) Int. Cl. H01L 23/473; H01L 25/18; H01L 23/498; H01L 23/31; H01L 21/56

(52) U.S. Cl. CPC H01L 23/473; H01L 25/18; H01L 23/49811; H01L 23/3121; H01L 21/56

(57) ABSTRACT

A power module includes a power semiconductor module having a semiconductor chip arranged on a substrate. A lead frame is arranged in electrical contact with the semiconductor chip. Abase plate includes cooling structures and micro channels that are connected to an inlet port and an outlet port. A bond layer connects the power semiconductor module and the base plate. A mold compound is arranged on the power semiconductor module, the bond layer and the base plate. The bond layer is encapsulated completely by the power semiconductor module, the base plate and the mold compound and the lead frame is arranged at least partially within the mold compound.

### CROSS-REFERENCE TO RELATED APPLICATIONS

This application is a national stage application of International Application No. PCT/EP2021/075486, filed on Sep. 16, 2021, which claims priority to European Patent Application No. 20196695.9, filed on Sep. 17, 2020, which applications are hereby incorporated herein by reference.

### TECHNICAL FIELD

The invention relates to a power module and a method for producing a power module.

### BACKGROUND

Power semiconductor modules used, for example, in inverters of electric cars, typically have to be cooled by a cooling unit using a liquid coolant. Thus, individual power semiconductor modules have to be integrated into the cooling unit for liquid cooling. This imposes the need for a reliable leak-tight seal between the power semiconductor modules and the cooling unit to prevent any risk of leakage into the power semiconductor modules.

State of the art is, for example, mounting the power semiconductor modules by screws with an O-ring sealing on the cooling unit. Alternatively, the power semiconductor modules can be mounted on a closed cooler. This requires a reliable bond between the power modules and the cooling unit with high thermal conductivity. However, this would require elevated process temperatures, which might cause damage and/or delamination of a casing of the power semiconductor modules.

Document DE 10 2011 0882 18 A1 describes an electronic power module, which is coupled with thermal coupling layers to a cooling element.

Document DE 10 2012 205590 A1 describes a power module for the use with an inverter and document WO 2015/176992 A1 describes a semiconductor power module having a heat interface, wherein the module is surrounded by a resin.

### SUMMARY

Embodiments of the invention provide a power module which has an improved reliability and a method for producing such a power module.

In one embodiment, a power module is provided comprises at least one power semiconductor module having at least one semiconductor chip arranged on a substrate comprising at least one electrical insulating layer. A lead frame arranged in electrical contact to the at least one semiconductor chip. A base plate comprises cooling structures and a bond layer connects the power semiconductor module and the base plate. A mold compound is arranged on the power semiconductor module, the bond layer and the base plate. The bond layer is encapsulated completely by the power semiconductor module, the base plate and the mold compound, and the lead frame is arranged at least partially within the mold compound.

Other embodiments are disclosed in more detail herein.

### BRIEF DESCRIPTION OF THE DRAWINGS

The subject-matter of the invention will be explained in more detail in the following with reference to exemplary embodiments which are illustrated in the attached drawings.

FIGS. 1 and 2 each schematically show a top view on a power module according to an exemplary embodiment of the invention.

FIGS. 3 and 4 each schematically show a cross-section through a power module according to an exemplary embodiment of the invention.

FIG. 5 shows an exemplary representation of a thermomechanical strain simulation of different power modules.

FIGS. 6, 7 and 8 each schematically show a cross-section through a power module used for the simulation.

The reference symbols used in the drawings, and their meanings, are listed in summary form in the list of reference symbols. In principle, identical parts are provided with the same reference symbols in the figures.

### DETAILED DESCRIPTION OF ILLUSTRATIVE EMBODIMENTS

Embodiments of the invention will first be described with respect to the figures in general. The figures will be described more thoroughly below.

A first aspect of the invention relates to a power module 1. The term “power” here and in the following, for example, refers to power modules, power semiconductor modules and/or semiconductor chips adapted for processing voltages and currents of more than 100 V and/or more than 10 A, exemplary voltages up to 1200 V and currents of several hundred amperes. For example, the power module 1 is used in automotive applications, such as electric vehicles, hybrid vehicles, motorbikes, buses, trucks, off-road construction vehicles, and charging stations.

The power module 1 has, for example, a main plane of extension. Lateral directions are aligned parallel to the main plane of extension and a vertical direction is aligned perpendicular to the main plane of extension.

According to the embodiment of the invention, the power module 1 comprises at least one power semiconductor module 2 having at least one semiconductor chip 3 arranged on a substrate 4 comprising at least one electrical insulating layer 6.

The semiconductor chip 3 is based, for example, on silicon or a wide bandgap material, exemplarily silicon carbide. The semiconductor chip 3 is, for example, formed as a diode and/or a switch. Such a switch is, for example, a transistor, a varistor, an insulated gate bipolar transistor, abbreviated as IGBT, or a metal oxide or insulator semiconductor field effect transistor, abbreviated as MOSFET.

The power semiconductor module 2, for example, comprises at least two semiconductor chips 3. The two semiconductor chips 3 are arranged on the substrate 4, for example, the same substrate. For example, one of the semiconductor chips is formed as a switch and the other of the semiconductor chips is formed as a diode. In this case, the switch and the diode are connected antiparallel to one another. The two semiconductor chips 3 being connected antiparallel to one another form, for example, a half bridge. For example, the power semiconductor module 2 comprises one or more half bridges. In this case, the power semiconductor module 2 comprises two or more semiconductor chips 3.

The substrate 4 comprises, for example, an electrical insulating material 6. The electrical insulating material 6 of the substrate 4 comprises or consists of a ceramic such as AlO, AlN and/or SiN.

According to the embodiment, the power module 2 comprises a lead frame 8 arranged in electrical contact to the semiconductor chip 3. The lead frame 8 comprises, for example, terminal parts 16, which are configured for external contacting of the power module 1. The lead frame 8 comprises or consists, for example, of a metal, exemplarily Cu.

According to the embodiment, the power module 1 comprises a base plate 9 comprising cooling structures 10. The power semiconductor module 2 is arranged on the base plate 9. The base plate 9 is configured, for example, to cool the power semiconductor module 2 during operation.

According to the embodiment, the power module 1 comprises a bond layer 11 connecting the power semiconductor module 2 and the base plate 9. The bond layer 11 comprises or consists, for example, of a metallic material. Thus, heat produced by the power semiconductor module 2 during operation can be dissipated particularly well in the direction of the cooling structures 10. The bond layer 11 is configured, for example, to attach the power semiconductor module 2 to the base plate 9, exemplarily in a mechanically stable manner.

According to the embodiment, the power module 1 comprises a mold compound 12 arranged on the power semiconductor module 2, the bond layer 11 and the base plate 9. For example, the mold compound 12 is in direct contact to the power semiconductor module 2, the bond layer 11 and the base plate 9. The mold compound 11 comprises or consists of an epoxy mold compound, exemplarily an epoxy resin. Advantageously, a strength of the attachment of the power semiconductor module 2 to the base plate 9 is thus further increased.

According to the embodiment of the power module 1, the bond layer 11 is encapsulated completely by the power semiconductor module 2, the base plate 9 and the mold compound 12. For example, the power semiconductor module 2 covers at least a part of an outer surface of the bond layer 11 facing the power semiconductor module 2. Further, the base plate 9 covers at least a part of the outer surface of the bond layer 11 facing the base plate 9. For example, the mold compound 12 covers a rest of the outer surface of the bond layer 11, which is not covered by the power semiconductor module 2 and the base plate 9. Therefore, the bond layer 11 is exemplarily three-dimensionally encapsulated. Exemplarily, the bond layer 11 does not comprise an outer surface not being covered by the power semiconductor module 2, the base plate 9 and the mold compound 12. Having such a mold compound 12, aging effects of the bond layer 11 can be reduced advantageously.

According to the embodiment of the power module 1, the lead frame 8 is arranged at least partially within the mold compound 12. For example, the terminal parts 16 of the lead frame 8 protrude from the mold compound 12 in order to be externally contactable.

In summary, such a power module 1 can provide, inter alia, the following advantages. Overall dimensions of the power module 1 can be reduced because additional overhead for mounting of the power semiconductor module 2 to the base plate 9 is omitted. Furthermore, the risk of coolant leakage into the power semiconductor module 2 is mitigated, since within such a power module 1, a metallurgical sealed cooler as the cooling structure can be used. Moreover, such a power module 1 has advantageously a comparably high cycling capability, since the bond layer 11 is encapsulated in the mold compound 12. Such a constrained bond layer 11 results in a reduced von Mises strain. Thus, a maximum operation temperature of the semiconductor chips 3 can be set exemplarily high, leading to savings of semiconductor area.

According to at least one embodiment of the power module 1, the bond layer 11 is a solder layer or a sinter layer.

According to at least one embodiment of the power module 1, the mold compound 12 is arranged at least in places in direct contact with a side surface of the base plate 9. The mold compound 12, for example, protrudes beyond the outer surface of the bond layer 11 in vertical direction, in direction to the base plate 9. This is to say that the mold compound 12 and the base plate 9 overlap in a side view. Advantageously, the bond layer 11 is thus further protected from external contamination.

According to at least one embodiment of the power module 1, the substrate 4 further comprises a first metallization layer 5 and a second metallization layer 7, and the electrical insulating layer 6 is arranged between the first metallization layer 5 and the second metallization layer 7.

For example, the semiconductor chip 3 is arranged on the first metallization layer 5. Further, the first metallization layer 5, for example is structured. In this case, the first metallization layer 5 covers the electrical insulating layer 6 only in regions. The first metallization layer 5 is, for example, structured to provide electrical conductors to which the semiconductor chip 3 is connected.

According to at least one embodiment of the power module 1, the base plate 9 has a protruding part 13 protruding beyond the bond layer 11 in lateral directions.

According to at least one embodiment of the power module 1, the mold compound 12 is arranged on an outer surface of the protruding part 13 in direct contact. For example, the mold compound 12 is arranged on a side surface of the protruding part 13 extending in vertical direction. Furthermore, the mold compound 12 is, for example, arranged on a top surface of the protruding part 13 extending in lateral directions, facing the power semiconductor module 2. According to this embodiment, the outer surface of the protruding part 13, on which the mold compound 12 is arranged, is formed from the side surface of the protruding part 13 and the top surface of the protruding part 13.

According to at least one embodiment of the power module 1, the cooling structures comprise pin fins. For example, the pin fins are arranged on a bottom surface of the base plate 9, facing away from the power semiconductor module 2. Each pin fin is exemplarily formed from a pillar extending in vertical direction. For example, all of the pin fins have a common direction of extension being parallel to the vertical direction. The pin fins are formed, for example, from the same material as the base plate 9, such as Cu. For example, the pin fins increase an area of the bottom surface of the base plate 9. Advantageously, heat dissipation can be improved because of such pin fins.

According to at least one embodiment of the power module 1, the base plate 9 comprises micro channels connected to at least one inlet port and at least one outlet port. For example, the micro channels are embedded in the base plate 9. “Embedded” means here, that an outer surface of the micro channels are completely enclosed by the material of the base plate 9. The micro channels are formed, for example, from rods. For example, a liquid coolant can flow from the inlet port through the micro channels to the outlet port. Exemplary, the liquid coolant is pumped from the inlet port via the micro channels to the outlet port. Advantageously, heat generated during operation of the power module 1 can be dissipated away from the power semiconductor module 2 via the base plate 9 comprising such micro channels particularly effectively.

According to at least one embodiment of the power module 1, the base plate 9 comprises interlocking features 14 configured to fix the mold compound 12 to the base plate 9. For example, an outer surface of the base plate 9 being in direct contact to the mold compound 12 comprises the interlocking features 14. The interlocking features 14 are formed, for example, from the same material as the base plate 9. The interlocking features 14 have the form, for example, of dimples, indents and/or grooves. The interlocking features 14 advantageously increase an adhesive force between the mold compound 12 and the base plate 9.

According to at least one embodiment, the power module 1 comprises at least two power semiconductor modules 2 being arranged spaced apart from one another. For example, the base plate 9 is a common base plate 9 for the power semiconductor modules 2. Advantageously, due to such a common base plate 9, a flow of the liquid coolant is particular good since there are no weld seams or sealing parts between the power semiconductor modules 2 within the base plate 9.

According to at least one embodiment of the power module 1, the mold compound 12 is arranged on the two power semiconductor modules 2.

According to at least one embodiment, the mold compound 12 comprises a recess 15 between the two power semiconductor modules 2. For example, the recess 15 does not overlap with the power semiconductor modules 2 in top view.

According to at least one embodiment of the power module 1, the recess 15 does not penetrate the mold compound 12 completely. For example, a height in vertical direction of the mold compound 12 between the two power semiconductor modules 2 is smaller than a height in vertical direction of the mold compound 12 over the two semiconductor modules. The mold compound 12, for example, is simply connected. This is to say that the mold compound 12 extends continuously over the semiconductor modules.

Advantageously, due to the recess 15 the risk of a delamination of the mold compound 12 due to a mismatch of coefficients of thermal expansion between the mold compound 12 and the semiconductor power module 1 components and the base plate 9 is decreased in comparison to a mold compound 12 without a recess 155. Further, a warpage of the power module 1 is thus also reduced.

According to at least one embodiment of the power module 1, the recess 15 penetrates the mold compound 12 completely. For example, the recess 15 exposes the base plate 9 between the two power semiconductor modules 2. For example, the mold compound 12 is multiple connected. This is to say that the mold compound 12 according to this embodiment is formed discontinuously.

A second aspect of the invention relates to a method for producing a power module 1. Preferably the method produces a power module 1 described herein above. All features disclosed in connection with the power module 1 are therefore also disclosed in connection with the method and vice versa.

According to at least one embodiment, the method comprises the step of providing at least one power semiconductor module 2, wherein at least one semiconductor chip 3 is bonded on a substrate 4 comprising at least one electrical insulating layer 6. Bonding refers here and in the following to soldering, sintering and/or welding, for example.

According to at least one embodiment, the method comprises the step of applying a lead frame 8 in electrical contact to the semiconductor chip 3.

According to at least one embodiment the method comprises the step of providing a base plate 9 comprising cooling structures 10.

According to at least one embodiment, the method comprises the step of bonding the power semiconductor module 2 to the base plate 9 with a bond layer 11. For the case that the power module 1 comprises more than one power semiconductor module 2, all the power semiconductor modules 2, for example, are bonded in a single process step to the base plate 9.

According to at least one embodiment, the method comprises the step of applying a mold compound 12 on the power semiconductor module 2, the bond layer 11 and the base plate 9, such that the bond layer 11 is encapsulated completely by the power semiconductor module 2, the base plate 9 and the mold compound 12, and the lead frame 8 is arranged at least partially within the mold compound 12. The mold compound 12 is applied, for example, via a transfer molding process or compression molding process. Using the transfer molding process, mold compound 12 volumes up to 120 cm3 can be achieved.

Exemplary, the step of applying the mold compound 12 is performed after the method step of bonding the power semiconductor module 2 to the base plate 9 with the bond layer 11.

Using such a method has the following advantages. In comparison to power modules according to the state of the art, the total number of method steps are reduced, since mounting of individual power semiconductor modules 2 on the base plate 9 is omitted. Further, an alignment accuracy between individual power semiconductor modules 2 is particularly accurate.

According to at least one embodiment of the method, the semiconductor chip 3 is bonded to the substrate 4 by soldering or sintering.

According to at least one embodiment of the method, the substrate 4 is a lead frame 8 being applied from a single-piece lead frame 8 with dam-bar structures. For example, the lead frame 8 having the dam-bar structures can comprise bars being in electrical contact to the semiconductor chip 3. The bars are configured to provide an electrical contact to the semiconductor chip 3. Further, the lead frame 8 having the dam-bar structures can comprise dams, wherein the dams are arranged between two bars and wherein the dams extend perpendicular to these bars in lateral directions. Exemplary, the dams surround semiconductor chip 3 and the substrate 4 completely in lateral directions. These dams can be used as a delimiting element for the mold compound 12 for the transfer molding process.

According to at least one embodiment of the method, the base plate 9 is pressed in the direction of the power semiconductor module 2 during the application of the mold compound 12. Exemplary, the base plate 9 is pressed in vertical direction in the direction of the power semiconductor module 2 during the application of the mold compound 12. Advantageously, such an encapsulated bond layer 11 is particularly well protected from external contaminations.

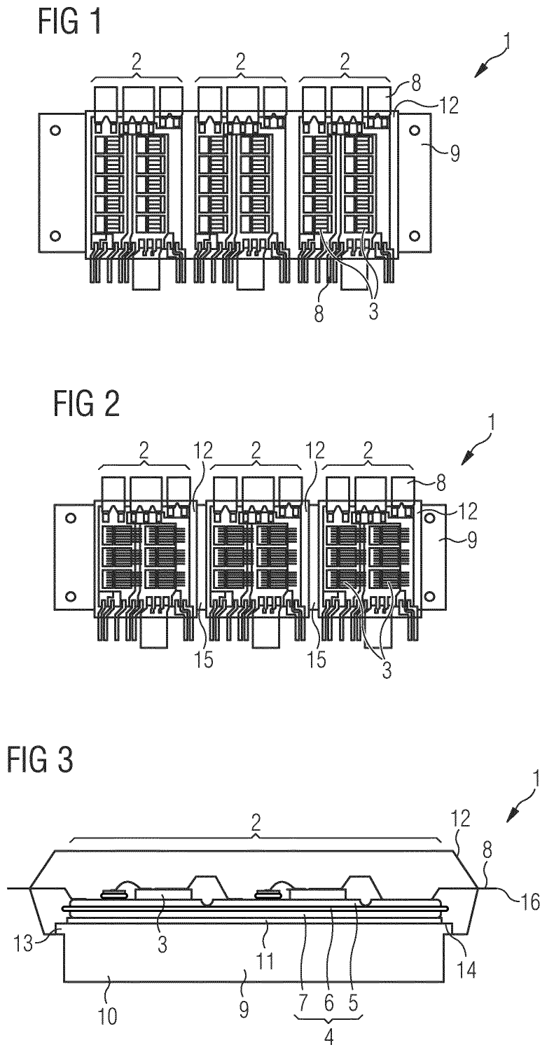

The power module 1 according to the exemplary embodiment of FIG. 1 comprises three power semiconductor modules 2, each having twenty semiconductor chips 3, wherein ten of the semiconductor chips 3 are formed of switches and ten of the semiconductor chips 3 are formed of diodes. Further, the power module 1 comprises a lead frame 8 arranged in electrical contact to the semiconductor chips 3.

The power module 1 further comprises a base plate 9, on which the semiconductor modules 2 are arranged on. The semiconductor modules 2 are attached to the base plate 9 with a bond layer 11, being described in more detail in connection with the exemplary embodiment of FIG. 3.

A mold compound 12 is arranged on the power semiconductor modules 2. The mold compound 12 is arranged continuously over all the semiconductor modules 2. This is to say that the mold compound 12 is simply connected.

Each power semiconductor module 2 shown in FIG. 2 comprise in contrast to FIG. 1 six semiconductor chips 3. In addition, in contrast to FIG. 1, the mold compound 12 comprises a recess 15 between neighboring power semiconductor modules 2. Each recess 15 penetrates the mold compound 12 completely, such that a base plate 9 between neighboring power semiconductor modules 2 is exposed. In this exemplary embodiment, the mold compound 12 is thus multiple connected.

The power module 1 according to the exemplary embodiment of FIG. 3 corresponds to a cross-section of a power module 1 according to FIG. 1 or 2. The semiconductor chips 3 of a power semiconductor module 2 are arranged on a substrate 4. The substrate 4 comprises a first metallization layer 5, an electrical insulating layer 6 and a second metallization layer 7. The electrical insulating layer 6 is arranged between the first metallization 5 layer and the second metallization layer 7.

The first metallization layer 5 is structured in regions, wherein the regions are electrically insulated from one another. Each semiconductor chip 3 is arranged on one of the regions. The regions of the first metallization layer 5 are interconnected according to this exemplary embodiment with bonding wires.

The power module 1 further comprises a lead frame 8. The lead frame 8 is configured to provide an electrical contact to the semiconductor chips 3 and is thus in electrical contact to the semiconductor chips 3. In this exemplary embodiment, the lead frame 8 is contacted to the first metallization layer 5. Exemplary, the lead frame 8 is in direct contact to a region of the first metallization layer 5. Further, the lead frame 8 comprises terminal parts 16, which are configured for external contacting of the power module 1.

The power semiconductor module 2 is arranged on a base plate 9 with a bond layer 11. The base plate 9 comprises cooling structures 10 in order to dissipate heat away from the power semiconductor module 2. Furthermore, due to the bond layer 11 the power semiconductor module 2 is attached to the base plate 9, exemplary, in a mechanical stable manner.

The base plate 9 is a plate having a protruding part 13 protruding beyond the bond layer 11 in lateral directions. The protruding part 13 comprises a top surface extending in lateral directions, facing the power semiconductor module 2. Further, the protruding part 13 comprises a side surface, connected to the top surface, extending in vertical direction. This is to say that an outer surface of the protruding part 13 is formed from the side surface of the protruding part 13 and the top surface of the protruding part 13. In addition, the top surface of the protruding part 13 and a top surface of the base plate 9, facing the power semiconductor module 2, are arranged in a common plane.

In addition a mold compound 12 is arranged on the power semiconductor module 2, the bond layer 11 and the base plate 9. The mold compound 12 is in direct contact to the power semiconductor module 2. Exemplary, all components of the power semiconductor module 2 are embedded in the mold compound 12. Further the bond layer 11 and the base plate 9 are also in direct contact to the mold compound 12.

Exemplary, the mold compound 12 is arranged on the outer surface of the protruding part 13, i.e. the side surface of the protruding part 13 and the top surface of the protruding part 13, in direct contact. Furthermore, the lead frame 8 is arranged at least partially within the mold compound 12. The terminal parts 16 of the lead frame 8 protrude from the mold compound 12 in order to be externally contactable.

It is further possible that the outer surface of the base plate 6 being in direct contact to the mold compound 12 comprises the interlocking features 14, i.e. dimples, indents and/or grooves.

Having such a mold compound 12, the bond layer 11 is completely encapsulated by the power semiconductor module 2, the base plate 6 and the mold compound 12. This is to say that the bond layer 11 is three-dimensionally encapsulated. The bond layer 11 has no outer surface being freely accessible.

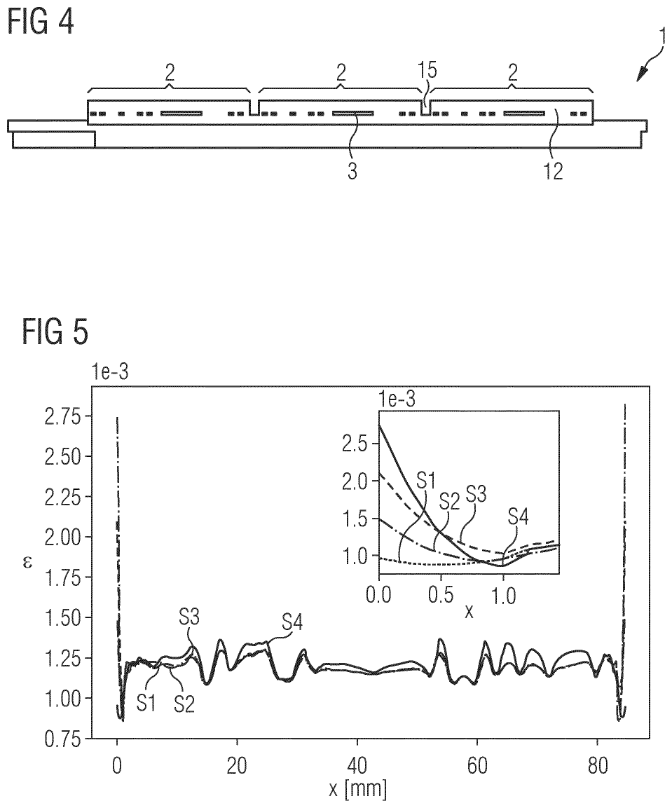

The mold compound 12 according to the exemplary embodiment of FIG. 4 comprises recesses 15, which do not penetrate the mold compound 12 completely. A height in vertical direction of the mold compound 12 between the direct neighboring power semiconductor modules 2 is smaller than a height in vertical direction of the mold compound 12 over direct neighboring semiconductor modules 2.

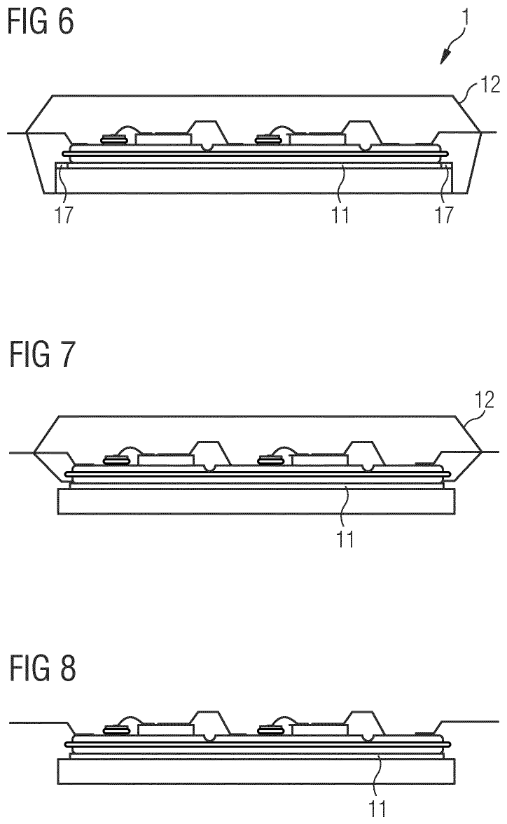

A thermomechanical strain behavior of different power modules is plotted according to the diagram in FIG. 5. A structure of the different power modules is shown in connection with FIGS. 3, 6, 7 and 8. The power module according to FIG. 3 is marked with a reference sign S1, the power module according to FIG. 6 is marked with a reference sign S2, the power module according to FIG. 7 is marked with a reference sign S3 and the power module according to FIG. 8 is marked with a reference sign S4.

In the diagram, strain values ε in arbitrary units of the respective power module S1, S2, S3 and S4 are provided on the y-axis. Here, the strain values ε correspond to an elastic strain in the respective bond layer 11 due to a temperature increase of 5 Kelvin. On the x-axis, a position x in mm of the respective power module S1, S2, S3 and S4 is provided.

The curves of S1, S2, S3, and S4 differ distinctively at an edges of the bond layer 11, since bond layers ii typically degrade by delaminating from the edges due to thermal cycles. The strain values ε of the edges of the bond layers ii of power modules S1, S2, S3 and S4 are also shown in the inset of the diagram. Because strain is proportional to stress, and eventually correlates to lifetime, the curves S1, S2, S3, and S4 can be used to make a qualitative lifetime assessment.

The strain values ε at the edge is lowest for the power module S1, since the bond layer 11 is fully encapsulated in mold compound 12. That is to say that the mold compound 12 compresses the bond layer 11 both in vertical direction and in lateral directions. In contrast, the corresponding strain value ε is highest for the power module S4, having no mold compound 12.

A bond layer 11 of the power module S3 according to FIG. 7 is not completely encapsulated. Since here a power semiconductor module 2 is first overmolded, and only subsequently bonded to a base plate 9, the bond layer 11 is exposed and not constrained. For the power module S3, the strain value ε is smaller compared to the power module S4. Further, the strain value ε of power module S3 is approximately twice as high as in the power module S1 because the mold compound 12 only stiffens the assembly in vertical direction, but the bond layer 11 is free of the mold compound 12 in lateral directions.

The power module S2 corresponds basically to the power module S1. For simulation reasons, the bond layer 11 of power module S2 comprises at its end regions a virtual soft element 17. This virtual soft element 17 surrounds the bond layer 11 in lateral directions. Hence, the bond layer 11 is compressed in vertical direction by the mold compound 12 but elongation in lateral directions is virtually unconstrained. This results in strain values ε between the power module S1 and power module S3.

Advantageously, such a simulation shows that encapsulating a bond layer 11 by a mold compound 12 will significantly enhance its lifetime. Hence, the power module S1 will result in higher thermal cycling capability compared to power modules S3 or S4.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art and practicing the claimed invention, from a study of the drawings, the disclosure, and the appended claims. In the claims, the word “comprising” does not exclude other elements or steps, and the indefinite article “a” or “an” does not exclude a plurality. A single processor or controller or other unit may fulfil the functions of several items recited in the claims. The mere fact that certain measures are recited in mutually different dependent claims does not indicate that a combination of these measures cannot be used to advantage. Any reference signs in the claims should not be construed as limiting the scope.

1-15. (canceled)

16. A power module comprising:
a power semiconductor module having a semiconductor chip arranged on a substrate;
a lead frame arranged in electrical contact with the semiconductor chip;
a base plate comprising cooling structures and micro channels that are connected to an inlet port and an outlet port;
a bond layer connecting the power semiconductor module and the base plate; and
a mold compound arranged on the power semiconductor module, the bond layer and the base plate, wherein the bond layer is encapsulated completely by the power semiconductor module, the base plate and the mold compound and wherein the lead frame is arranged at least partially within the mold compound.

17. The power module according to claim 16, wherein the bond layer comprises a solder layer or a sinter layer.

18. The power module according to claim 16, wherein the mold compound is in direct contact on a side surface of the base plate at least in places.

19. The power module according to claim 16, wherein the substrate comprises:
a first metallization layer;
a second metallization layer; and
an electrical insulating layer arranged between the first metallization layer and the second metallization layer.

20. The power module according to claim 16, wherein:
the base plate has a protruding part protruding beyond the bond layer in lateral directions; and
the mold compound is in direct contact with an outer surface of the protruding part.

21. The power module according to claim 16, wherein the cooling structures comprises pin fins.

22. The power module according to claim 16, wherein the base plate comprises interlocking features configured to fix the mold compound to the base plate.

23. The power module according to claim 16, wherein the power module comprises a plurality of power semiconductor modules arranged spaced apart from one another, the mold compound being arranged on the power semiconductor modules.

24. The power module according to claim 23, wherein the mold compound comprises a recess between two of the power semiconductor modules.

25. The power module according to claim 24, wherein the recess does not penetrate the mold compound completely.

26. The power module according to claim 24, wherein the recess penetrates the mold compound completely.

27. A power module comprising:
a plurality of power semiconductor modules, each power semiconductor module having a plurality of semiconductor chips arranged on a substrate;
a lead frame arranged in electrical contact to with the semiconductor chips;
a base plate comprising cooling structures and also comprising micro channels that are connected to inlet ports and outlet ports;
a bond layer connecting the power semiconductor modules and the base plate; and
a mold compound arranged on the power semiconductor modules, the bond layer and the base plate, wherein the bond layer is encapsulated completely by the power semiconductor modules, the base plate and the mold compound and wherein the lead frame is arranged at least partially within the mold compound.

28. The power module according to claim 27, wherein the semiconductor chips include a first semiconductor chip comprising a switch and a second semiconductor chip comprising a diode, the switch and the diode being connected antiparallel to one another to form a half bridge.

29. The power module according to claim 27, wherein:
the base plate has a protruding part protruding beyond the bond layer in lateral directions; and
the mold compound is in direct contact with an outer surface of the protruding part.

30. The power module according to claim 27, wherein the base plate comprises interlocking features configured to fix the mold compound to the base plate.

31. The power module according to claim 27, wherein the mold compound comprises a recess between two of the power semiconductor modules.

32. A method for producing a power module, the method comprising:
providing a power semiconductor module having semiconductor chip bonded on a substrate that comprises an electrical insulating layer;
applying a lead frame in electrical contact with the semiconductor chip;
bonding the power semiconductor module to a base plate with a bond layer, the base plate comprising cooling structures and micro channels that are connected to an inlet port and an outlet port;
applying a mold compound on the power semiconductor module, the bond layer and the base plate, such that the bond layer is encapsulated completely by the power semiconductor module, the base plate and the mold compound, and the lead frame is arranged at least partially within the mold compound.

33. The method according to claim 32, further comprising bonding the semiconductor chip to the substrate by soldering or sintering.

34. The method according to claim 32, wherein the substrate comprises a single-piece lead frame with dam-bar structures.

35. The method according to claim 32, wherein applying the mold compound comprises pressing the base plate in a direction of the power semiconductor module.
